(19) United States
(12) Patent Application Publication
(10) Pub. No.: US 2017/0208710 A1
(43) Pub. Date: Jul. 20, 2017

(54) ELECTRICAL COMPONENT WITH ELECTRICAL TERMINAL IN WALL OF SHIELD FRAME

(71) Applicant: Apple Inc., Cupertinio, CA (US)

(72) Inventors: Albert Wang, Sunnyvale, CA (US); Paul A. Martinez, Cupertino, CA (US)

(21) Appl. No.: 15/409,260

(22) Filed: Jan. 18, 2017

Related U.S. Application Data
(60) Provisional application No. 62/280,049, filed on Jan. 18, 2016.

(51) Int. Cl. H05K 9/00; H05K 3/30; G06F 1/16; G06F 1/26; H05K 1/18

(52) U.S. Cl. CPC H05K 9/0024; G06F 1/26; H05K 1/181; G06F 1/1613; H05K 3/303; H05K 9/0039; H05K 2201/10015; H05K 2201/10022; H05K 2201/1003; H05K 2201/1006

(57) ABSTRACT

The present disclosure relates to shield frames that reduce electromagnetic interference in electrical devices. The shield frames may be formed by coupling a shield frame lid to a ground connection of the circuit board through terminations in electrical components. The terminations in these electrical components thus may act both as a ground termination for the component as well as a ground connection for the shield frame. The components may be disposed in the perimeter of the circuit board to establish, with or without additional conductive posts, sections of the shield frame wall.

### CROSS REFERENCE

This application claims priority from and the benefit of Provisional U.S. Patent Application No. 62/280,049, entitled “COMBINED FILTER COMPONENTS WITH INTEGRATED SHIELD FRAME TERMINATIONS” filed Jan. 18, 2016, which is hereby incorporated by reference in its entirety for all purposes.

### BACKGROUND

The present disclosure relates generally to shielding structures for electrical circuit substrates (e.g., printed circuit boards or flexible circuit boards) and packaging of electrical devices. Specifically, this disclosure describes an electrical component having a node (e.g., ground terminal) that is used as part of a wall of a shield frame.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Electrical circuit boards in an electrical device may be affected by external electromagnetic interference. This electromagnetic interference may be created by neighboring circuit boards within the device, other electrical devices, or a number of natural phenomena. This electromagnetic interference may affect the normal behavior of electrical devices by, for example, generating spurious currents, changing memory states, or affecting sensors and sensor buffers. To mitigate these undesired effects, structures or devices such as shield frames may be employed. Shield frames are metal covers that may be mounted above a circuit board. A shield frame may form a Faraday cage around components, routes, and traces that are encased by the shield frame, thereby protecting them from some electromagnetic interference. Since shield frames may have better performance if connected to a ground connection of the electrical circuit board, shield frames may couple to a post connected to an electrical ground of the circuit board. The use of dedicated posts located along the perimeter of the circuit board may reduce the available space in the circuit board for electrical circuit components.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

This disclosure generally relates to generally to methods and structures for electromagnetic shielding of electrical circuits and/or circuit boards. In one example, a shielded printed circuit board is described. The shielded printed circuit board may have an electrical component having a ground termination coupled to a ground of the printed circuit board, and a shield frame that is coupled to the ground of the printed circuit board through the ground termination of that component.

In another embodiment, an electrical device may be described. The electrical device may have a module that has a printed circuit board and a set of perimeter components coupled to the printed circuit board. Each perimeter component may have at least one ground termination. The module may also have a shield frame lid that is electrically coupled to the ground of the electrical module through the ground terminations of the perimeter components.

In another example, a method to produce shielded printed circuit boards is discussed. The method includes attaching an electrical component to a printed circuit board and coupling at least one ground terminal of the electrical component to a ground of the printed circuit board. The method also includes attaching a shield frame to the ground terminal of the electrical component.

### BRIEF DESCRIPTION OF THE DRAWINGS

Various aspects of this disclosure may be better understood upon reading the following detailed description and upon reference to the drawings in which:

FIG. 1 is a diagram of an electrical device that may benefit from the use of shield frames coupled to components having integrated shield frame terminations, in accordance with an embodiment;

FIG. 2 is a perspective view of a notebook computer that may benefit from the inclusion of shield frames coupled to components having integrated shield frame terminations, in accordance with an embodiment;

FIG. 3 is a front view of a hand-held device that may benefit from the inclusion of shield frames coupled to components having integrated shield frame terminations, in accordance with an embodiment;

FIG. 4 is a front view of a portable tablet computer that may benefit from the inclusion of shield frames coupled to components having integrated shield frame terminations, in accordance with an embodiment;

FIG. 5 is a diagram of a desktop computer that may benefit from the inclusion of shield frames coupled to components having integrated shield frame terminations, in accordance with an embodiment;

FIG. 6 presents a front and a side view of a wearable electrical device that may benefit from the inclusion of shield frames coupled to components having integrated shield frame terminations, in accordance with an embodiment;

FIG. 7 presents a perspective view of a region of an electrical circuit board shielded with a shield frame coupled to a component with an integrated shield frame termination located in an end of the component, in accordance with an embodiment;

FIG. 8 presents a perspective view of a region of an electrical circuit board shielded with a shield frame coupled to a component having an integrated shield frame termination located in the body of the component, in accordance with an embodiment;

FIG. 9 presents a perspective of a region of an electrical circuit board shielded with a shield frame coupled to posts in the circuit board, in accordance with an embodiment; and

FIG. 10 illustrates a method for assembling an electrical circuit board with a shield frame coupled to components with integrated shield frame terminations, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logic OR) and not exclusive (e.g., logic XOR). In other words, the phase “A or B” is intended to mean A, B, or both A and B.

In the embodiments described herein, we describe electrical coupling between shield frame and a ground of an electrical circuit through a ground terminal of electrical components. The terms “components” and “electrical components” refer to electrical devices that may perform other functions in the electrical circuit, beyond the coupling of the shield frame. Examples may include resistors, capacitors, inductors, diodes, transistors, or integrated circuits. Note that, in this sense, electrical components may have at least one terminal that is not connected to the ground of the electric circuit. By contrast, the term “post” is intended to refer to conductor structures that do not provide any other function in the electrical circuit board and couples only to a ground terminal of the circuit board.

Many electrical devices may include electrical circuits that may be vulnerable to electromagnetic interference. Emissions from environmental and man-made radiation processes may generate pulses of electromagnetic waves that can interact with electrons and/or other carrier charges in wires, routes, and electrical circuits. Perturbations such as spurious currents and voltages on components of the electrical circuits may arise due to electromagnetic interference. These perturbations may lead to malfunctions in the electrical devices, as they may alter state of memory elements in digital systems or affect current and voltage levels in oscillators, amplifiers, sensors, actuators and other analog components. In certain situations, electromagnetic radiation may cause damage to electrical circuit components and/or the circuit board.

To mitigate effects from electromagnetic interference, shielding techniques may be used. Shielding may include a shield frame that envelopes the electrical circuit components to be protected from electromagnetic emissions from external sources, which may include solar radiation, cosmic radiation, radiation from nuclear materials in the environment as well as radio-frequency transmissions, microwave- and infrared-producing equipment, light sources, x-ray emitters for diagnostic and/or research uses, among other external sources. In some situations, the electromagnetic interference may come from another component of the same electrical circuit device. For example, relatively large currents and voltages in a power supply may generate electromagnetic interference signals that may affect neighboring electrical circuits. In these situations, the shield frame may, additionally or alternatively, reduce interfering electromagnetic emissions from leaving an electrical circuit board.

Shield frames may reduce the electromagnetic interference by allowing free motion of charge carriers in the frame structure. As electromagnetic radiation hits a conducting frame, the free motion of charges may lead to an absorption and/or reflection of the electromagnetic radiation in the frame structure, in a process similar to those of Faraday cage structures. As a result, electromagnetic radiation does not reach the protected components with the same intensity. Shield frames (e.g., shield cans) may also be electrically coupled to a ground connection in the electrical circuit board, which may improve the shielding performance of the structure. Embodiments described herein include electrical circuit components and devices that may be used to couple electrically the shield frames to a ground connection in an electrical circuit board, such as a printed circuit board. In some embodiments, conductive posts may also be used in the perimeter of the circuit board to be shielded. In some embodiments, an electrical termination of a perimeter component (i.e., an electrical component along a perimeter of the shield frame) may also be used to provide the coupling in the place of a conductive post, which reduces the number of components attached to a PCB and increases efficiency in the circuit board usage. The ground terminal in the perimeter component, as well as the posts, may form part of the shield frame wall. By using a node of an electrical circuit component to form the shield frame wall, the total volume involved to encase the same number of electrical circuit components may be reduced.

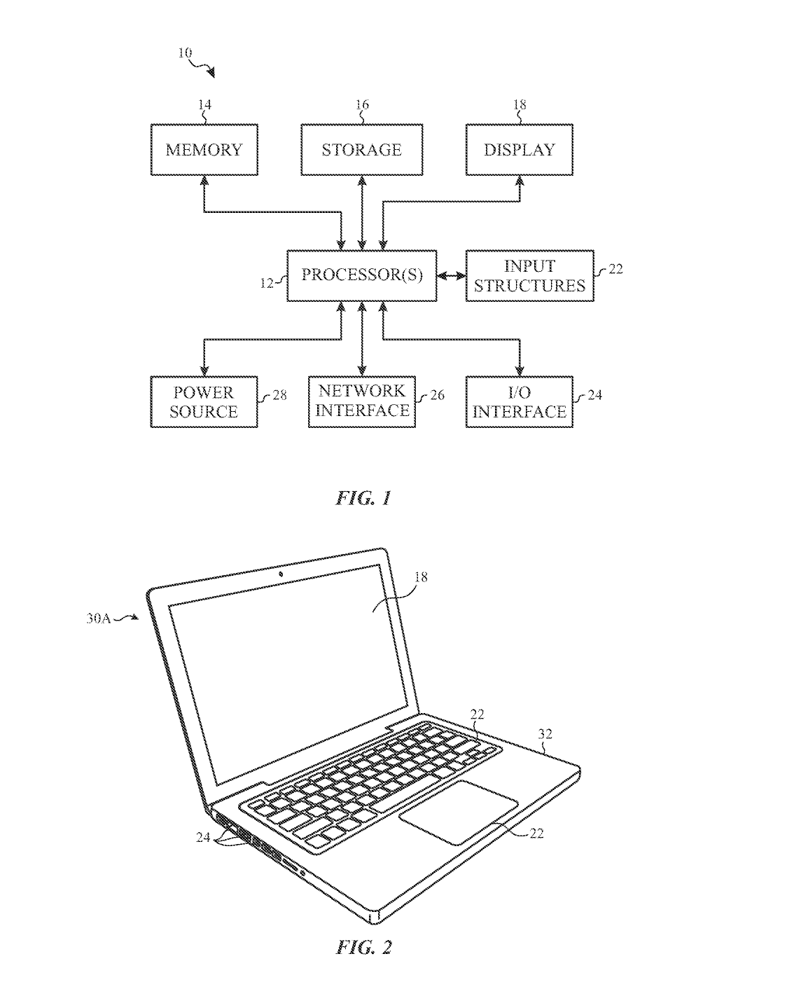

With the preceding in mind, a general description of suitable electronic devices that may include and use shield frames and components with integrated shield frame terminations. FIG. 1 is a block diagram of an electronic device 10, in accordance with an embodiment of the present disclosure. The electronic device 10 may include, among other things, one or more processor(s) 12, memory 14, storage or nonvolatile memory 16, a display 18, input structures 22, an input/output (I/O) interface 24, network interface 26, and a power source 28. The various functional blocks shown in FIG. 1 may include hardware elements (including circuitry), software elements (including computer code stored on a computer-readable medium), or a combination of both hardware and software elements. Embodiments of electrical components having integrated shield frame terminations as the ones described herein may be attached to printed circuit boards (PCBs) in the circuitry of the various functional blocks of FIG. 1 to reduce emissions of interfering electromagnetic radiation and/or mitigate malfunctions due to external interference. It should be noted that FIG. 1 is merely one example of a particular implementation and is intended to illustrate the types of components that may be present in electronic device 10.

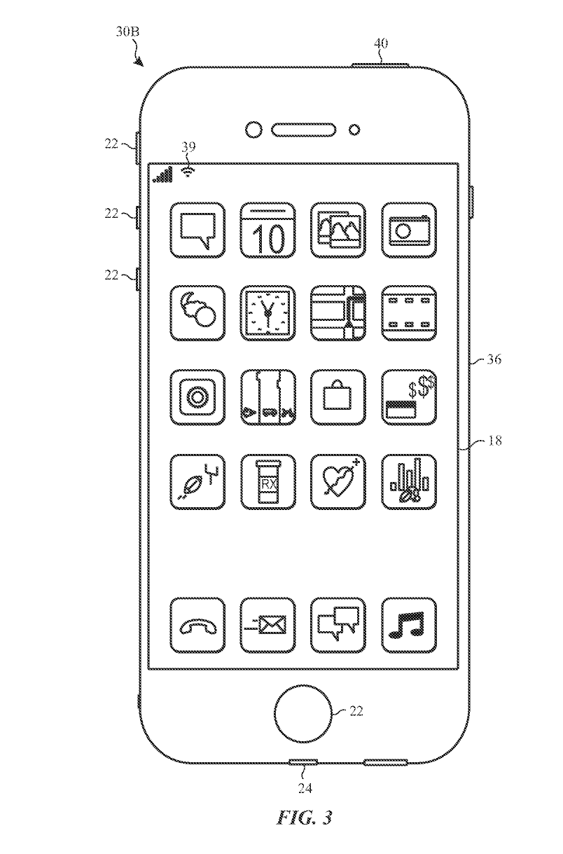

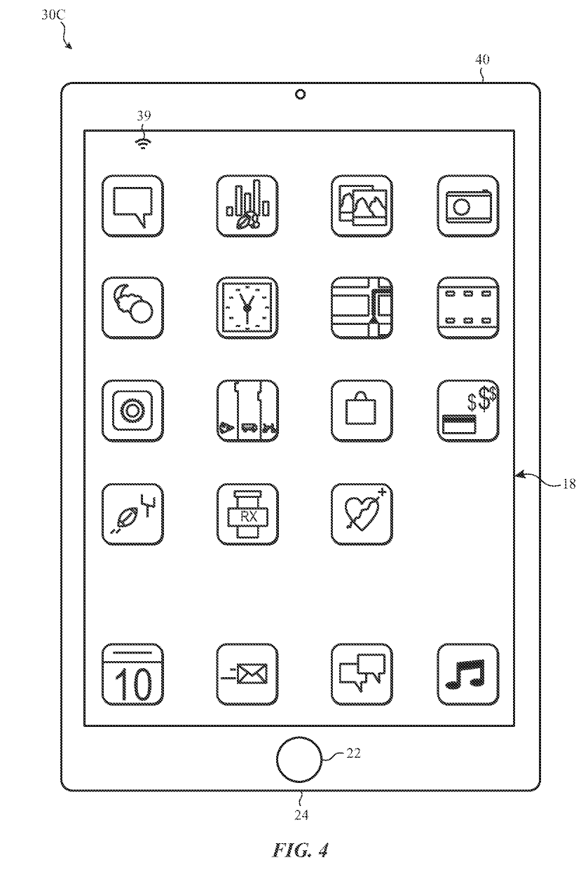

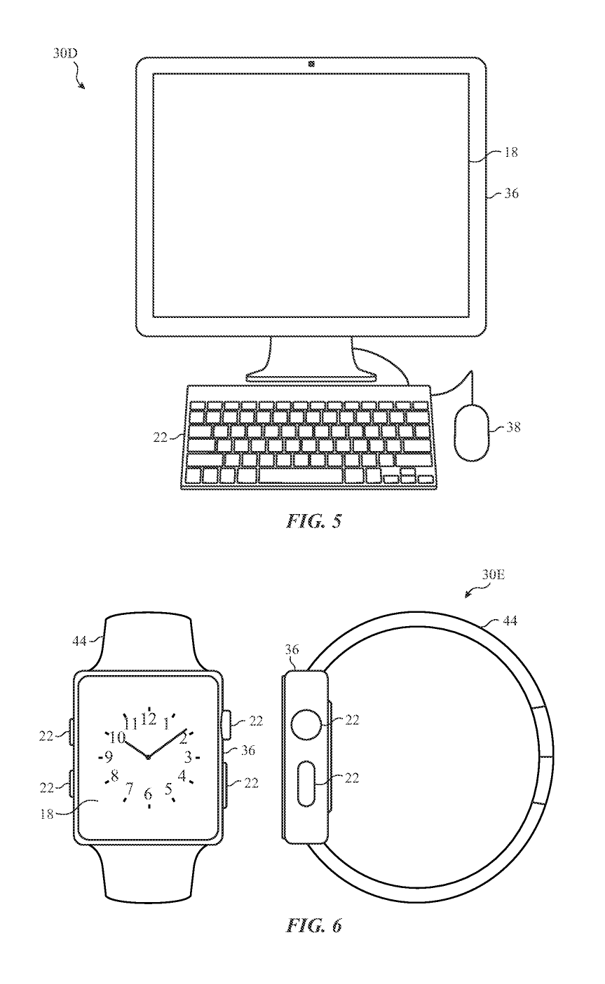

By way of example, the electronic device 10 may represent a block diagram of a notebook computer 30A depicted in FIG. 2, handheld devices 30B, 30C depicted in FIG. 3 and FIG. 4 respectively, a desktop computer 30D depicted in FIG. 5, a wearable electronic device 30E depicted in FIG. 6, or similar devices. It should be noted that the processor(s) 12 and/or other data processing circuitry may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 and/or other data processing circuitry may be operably coupled with the memory 14 and the nonvolatile storage 16 to perform various algorithms. Such programs or instructions executed by the processor(s) 12 may be stored in any suitable article of manufacture or computer program product that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. Moreover, programs (e.g., an operating system) encoded on the memory 14 or the nonvolatile storage 16 may also include instructions that may be executed by the processor(s) 12 to allow the electronic device 10 to provide various functionalities. In certain situations, electromagnetic interference may alter contents stored in memory 14 or nonvolatile storage 16 and, as a result, electromagnetic shielding may increase the reliability of data and software present in electronic device 10.

In certain embodiments, the display 18 may be a liquid crystal display (e.g., LCD), which may allow users to view images generated on the electronic device 10. In some embodiments, the display 18 may include a touch screen (an input structure 22), which may allow users to interact with a user interface of the electronic device 10. Furthermore, it should be appreciated that, in some embodiments, the display 18 may include one or more light emitting diode (e.g., LED, OLED, AMOLED, etc.) displays, or some combination of LCD panels and LED panels. Electromagnetic interference shielding may improve the performance of touch screen interfaces and reduced pixel failures and glitches during operation of display 18. The input structures 22 of the electronic device 10 may allow a user to interact with the electronic device 10 (e.g., pressing a button to increase or decrease a volume level).

The I/O interface 24 may allow electronic device 10 to interface with various other electronic devices. The I/O interface 24 may include various communications interfaces, such as universal serial bus (USB) ports, serial communications ports (e.g., RS232), Apple's Lightning® connector, or other communications interfaces. The network interface 26 may also allow electronic device 10 to interface with various other electronic devices and may include, for example, interfaces for a personal area network (e.g., PAN), such as a Bluetooth network, for a local area network (e.g., LAN) or wireless local area network (e.g., WLAN), such as an 802.11x Wi-Fi network, and/or for a wide area network (e.g., WAN), such as a 3rd generation (e.g., 3G) cellular network, 4th generation (e.g., 4G) cellular network, or long term evolution (e.g., LTE) cellular network. The network interface 26 may include an interface for, for example, broadband fixed wireless access networks (e.g., WiMAX), mobile broadband Wireless networks (e.g., mobile WiMAX), asynchronous digital subscriber lines (e.g., ADSL, VDSL), digital video broadcasting-terrestrial (DVB-T) and its extension DVB Handheld (DVB-H), Ultra-Wideband (UWB), alternating current (AC) power lines, and so forth. It should be noted that network interface 26 may have dedicated hardware (e.g., antennas) for capturing electromagnetic signals (e.g., radiofrequency transmissions). Note that electromagnetic shielding may decrease the reception performance of an antenna. Therefore, in certain circuit boards for wireless network interfaces 26, the shield frame may limit its extension to signal processing circuitry (e.g., tuning circuitry, phase-locked loop (PLL), transceiver, analog-to-digital converter, filters). In these circuit boards, the antenna and receiver amplifiers may be located outside the shield frame.

In some applications, input structures 22, the I/O interfaces 24 and/or network interfaces 26 may employ radiofrequency (RF) circuitry modules. Due to the high-frequency nature of certain RF signals, these circuits may be particularly susceptible to electromagnetic interference. Accordingly, the use of shield frames may increase reliability of input structures 22, I/O interfaces 24, and/or network interfaces 26. As further illustrated, the electronic device 10 may include a power source 28. The power source 28 may include any suitable source of power, such as a rechargeable lithium polymer (e.g., Li-poly) battery and/or an alternating current (e.g., AC) power converter. The power source 28 may be removable, such as replaceable battery cell. Large currents and voltages as present in power source 28 circuitry may, in some electronic devices 10, lead to emission of interfering electromagnetic radiation. As a result, shield frames in power source 28 circuitry may reduce any interference from this circuitry to other components of electronic device 10.

In certain embodiments, the electronic device 10 may take the form of a computer, a portable electronic device, a wearable electronic device, or other type of electronic device. Such computers may include computers that are generally portable (e.g., such as laptop, notebook, and tablet computers) as well as computers that are generally used in one place (e.g., such as conventional desktop computers, workstations and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of the notebook computer 30A, is illustrated in FIG. 2 in accordance with an embodiment of the present disclosure. The depicted computer 30A may include a housing or enclosure 32, a display 18, input structures 22, and ports of the I/O interface 24. In one embodiment, the input structures 22 (e.g., such as a keyboard and/or touchpad) may be used to interact with the computer 30A, such as to start, control, or operate a GUI or applications running on computer 30A. For example, a keyboard and/or touchpad may allow a user to navigate a user interface or application interface displayed on display 18.

FIG. 3 depicts a front view of a handheld device 30B, which represents an embodiment of the electronic device 10. The handheld device 30B may represent, for example, a portable phone, a media player, a personal data organizer, a handheld game platform, or any combination of such devices. By way of example, the handheld device 30B may be a model of an iPod® or iPhone® available from Apple Inc. of Cupertino, Calif. FIG. 4 depicts a front view of another handheld device 30C, which represents another embodiment of the electronic device 10. The handheld device 30C may represent, for example, a tablet computer, or one of various portable computing devices. By way of example, the handheld device 30C may be a tablet-sized embodiment of the electronic device 10, which may be, for example, a model of an iPad® available from Apple Inc. of Cupertino, Calif.

The handheld devices 30B and 30C may each include similar components. For example, an enclosure 36 may protect interior components from physical damage. Enclosure 36 may also shield the handheld devices 30B and 30C from electromagnetic interference. The enclosure 36 may surround the display 18, which may display indicator icons 39. The indicator icons 39 may indicate, among other things, a cellular signal strength, Bluetooth connection, and/or battery life. The I/O interfaces 24 may open through the enclosure 36 and may include, for example, an I/O port for a hard wired connection for charging and/or content manipulation using a connector and protocol, such as the Lightning connector provided by Apple Inc., a universal serial bus (e.g., USB), one or more conducted radio frequency connectors, or other connectors and protocols.

User input structures 22, 40, in combination with the display 18, may allow a user to control the handheld devices 30B or 30C. For example, the input structure 40 may activate or deactivate the handheld device 30B or 30C, one of the input structures 22 may navigate a user interface of the handheld device 30B or 30C to a home screen, a user-configurable application screen, and/or activate a voice-recognition feature of the handheld device 30B or 30C, while other of the input structures 22 may provide volume control, or may toggle between vibrate and ring modes. In the case of the handheld device 30B, additional input structures 22 may also include a microphone may obtain a user's voice for various voice-related features, and a speaker to allow for audio playback and/or certain phone capabilities. Portable devices 30B and 30C may printed circuit board having shield frames with integrated terminations to improve the efficiency in space utilization.

Turning to FIG. 5, a computer 30D may represent another embodiment of the electronic device 10 of FIG. 1. The computer 30D may take any suitable form of computer, such as a desktop computer, a server, or a notebook computer, but may also be a standalone media player or video gaming machine. By way of example, the computer 30D may be an iMac®, a MacBook®, or other similar device by Apple Inc. It should be noted that the computer 30D may also represent a personal computer (e.g., PC) by another manufacturer. A similar enclosure 36 may be provided to protect and enclose internal components of the computer 30D such as a dual-layer display. In certain embodiments, a user of the computer 30D may interact with the computer 30D using various peripheral input devices, such as input structures 22 (e.g., the keyboard or mouse 38), which may connect to the computer 30D via a wired I/O interface 24 and/or wireless I/O interface.

Similarly, FIG. 6 depicts a wearable electronic device 30E representing another embodiment of the electronic device 10 of FIG. 1 that may be configured to operate using the techniques described herein. By way of example, the wearable electronic device 30E, which may include a wristband 44, may be an Apple Watch® by Apple, Inc. However, in other embodiments, the wearable electronic device 30E may include any wearable electronic device such as, for example, a wearable exercise monitoring device (e.g., pedometer, accelerometer, heart rate monitor), or other device by another manufacturer. The display 18 of the wearable electronic device 30E may include a touch screen (e.g., LCD, OLED display, active-matrix organic light emitting diode (e.g., AMOLED) display, and so forth), which may allow users to interact with a user interface of the wearable electronic device 30E.

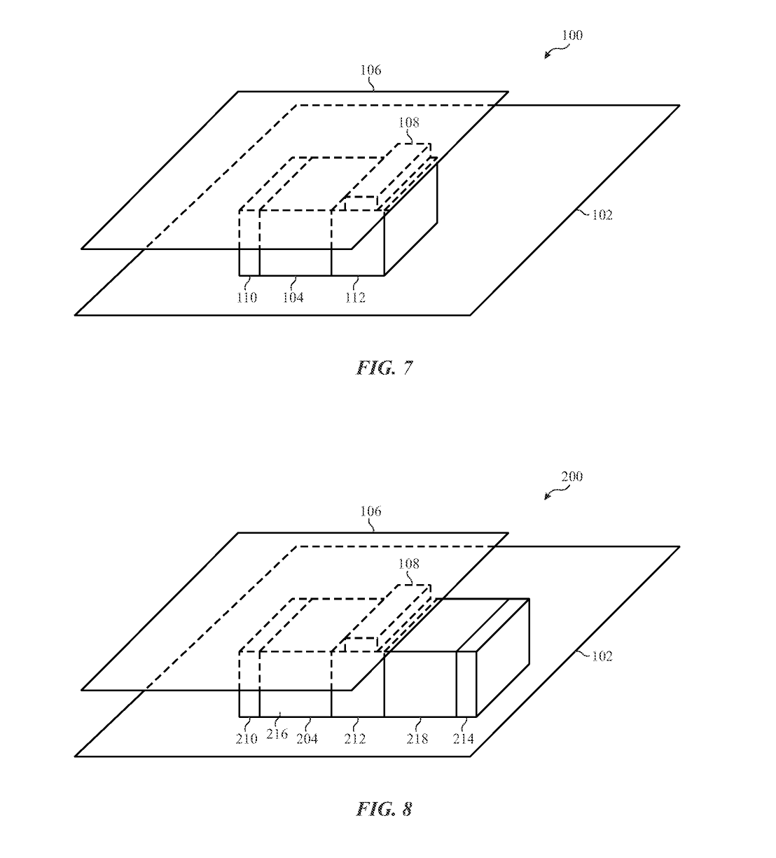

As discussed above, components may have integrated terminations that may provide ground connection both to the component as well as to a ground of an electrical circuit device. FIG. 7 illustrates a region 100 of a PCB 102 that may be shielded from electromagnetic interference. PCB 102 may have an electrical component 104 that may be used to provide grounding to a shield frame lid 106. As used herein, an electrical component may represent any suitable circuit element that has at least two terminations, allowing the electrical component to alter an electrical signal from one termination to the other (and/or vice versa). The component 104 may represent, for example, a resistor with at least two terminations, a capacitor with at least two terminations, an inductor with at least two terminations, a diode with at least tow terminations, some combination of any of these, or even more complex circuit components, such as integrated circuit or data-processing components.

In the example shown in FIG. 7, the component 104 may have a termination 110 coupled to a route on PCB 102. The component 104 may also have an integrated ground termination 112 coupled to the ground of PCB 102. Integrated ground termination 112 may also be coupled do shield frame lid 106 through a conductive structure 108. Conductive structure 108 may be, for example, a conductive adhesive or a conductor soldered or welded to component 104 and/or to shield frame lid 106. Conductive structure 108 may also be formed (e.g., pre-formed, pre-printed, pre-bumped with ball grid array) during assembly of component 104. This may allow for the conductive structures 108 on other electrical components similar to component 104 to have a common amount of conductive structure 108, such that the shield frame lid 106 to sit flat across the various electrical components and/or electrical posts when the shield frame lid 106 is installed. In some cases, conductive structure 108 may also raise the shield frame lid 106, providing a clearance between shield frame lid 106 and termination 110.

Note that the FIG. 7 illustrates one point of support for shield frame lid 106. Shield frame lid 106 may be supported by other components similar to component 104, or by other components or posts, as further discussed below. Component 104 may be any suitable component that has a terminal connected to a ground. Examples that may be employed as a component 104 include resistors, capacitors, inductors, diodes, and any other electrical device having at least two terminals. Note that the ground termination 112 of component 104 may be a part of the shielding frame wall. Therefore, care may be taken such that the effects of electromagnetic radiation in ground termination 112 (e.g., movement of electrons) does not affect operation of component 104. Component 104 may be a metal, a ceramic, a semi-conductor (e.g., silicon), or a plastic electrical component. Note further that, as the ground termination 112 is located in an end of component 104, the entire component 104 may be contained within the shield frame formed by ground terminations 112 and the shield frame lid 106 and, therefore, may be protected from electromagnetic interference.

In some situations, the component may not be entirely disposed within a shield frame wall. FIG. 8 illustrates a region 200 of a PCB 102 that may be shielded from electromagnetic interference employing a component 204 that has a region outside the shield frame. In this example, component 204 of PCB 102 presents terminal 210, a ground terminal 212 and an unshielded terminal 214. Shield frame lid 106 may be coupled to ground terminal 212 via conducive structure 108. As illustrated, ground terminal 212 is present in a middle region of component 204, which may determine the boundaries of the shield frame wall. As a consequence, terminal 210 and portion 216 of component 204 may be located within the shield frame wall while portion 218 and unshielded terminal 214 may be located outside the shield frame wall.

In some implementations, all electrical elements of component 204 are contained within portion 216 and portion 218 is merely a conducting body with a structural function. For example, component 204 may be a decoupling capacitor with a capacitive interface between terminal 210 and ground terminal 212 and portion 218 provides a conductive path (e.g., a short) between terminal 210 and unshielded terminal 214. In other implementations, portion 218 may have an electrical circuit element such as an inductor, a ferrite, a capacitive interface, a diode interface, or some other electrical element. For example, in some situations component 204 may be used to form a bulkhead filter. In such a design portion, 218 may have an adjusted impedance to drive current into the shield frame region.

Region 300 in FIG. 9 illustrates a shield frame lead 106 that is supported by posts instead of components with integrated shield frame terminations. PCB 102 may have a component 302 and a component 304. Furthermore, PCB 102 also has posts 306 and 308 that may be coupled to shield frame lead 106 through conductive structures 310 and 312, respectively. Similarly, to conductive structure 108, conductive structures 310 and 312 may be formed from conductive adhesives. Note that conductive structures 310 and 312 provide a clearance that prevents shield lid 106 from contact with components 302 and 304. Posts 306 and 308 may be employed in regions of the circuit board in which no suitable component was identified during the design of the PCB 102 layout.

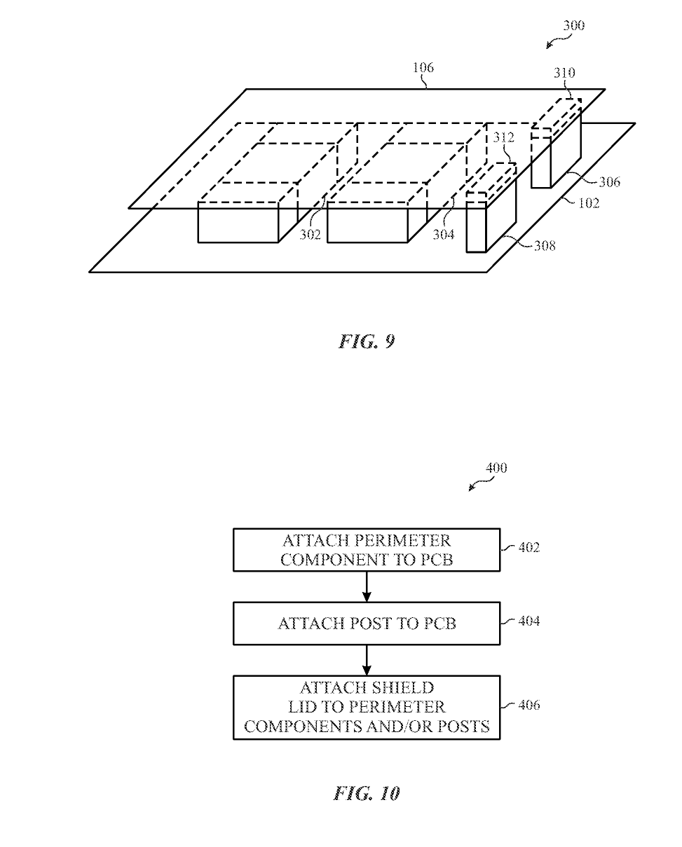

With the foregoing in mind, method 400 in FIG. 10 illustrates a method to assemble a printed circuit board having a shield frame coupled to the PCB ground using integrated component terminations. In a process 402, perimeter components may be attached to the PCB. Perimeter components may be components that were identified during the design of the PCB to have suitable ground terminations that may provide coupling between shield frame and the PCB ground. As discussed above, the ground terminations may be in an end or in the middle of the body of the perimeter component. Some applications may employ filter components (e.g., capacitors, inductors) that provide electrical coupling between the circuit board and other modules of the electrical device.

In regions of the perimeter of the shield frame (e.g., shield frame wall) without a perimeter component, posts may be attached (process 404) to the PCB. Posts may be coupled to ground connections in the PCB and may be placed to form, with perimeter components, the shield frame wall. Spacing (e.g., gaps) between posts and perimeter components may be adjusted based on the range of frequencies electromagnetic interference targeted. For example, a gap between neighboring perimeter components and neighboring posts may be limited to a maximum gap that may be chosen based on the frequency of the electromagnetic interference of interest. In one particular example, gaps of about 50 μm or so may be used to reduce electromagnetic interference in the 60 GHz range. Note that the entire perimeter of the shield frame may have either a perimeter component or a post. Increased usage in perimeter components may increase the efficiency of footprint resources, which may allow a reduced size for electrical device. Note further that even perimeter components that are not functional (i.e., not wired to a circuit on the circuit board) may be used to provide ground connections to the shield frame. Such perimeter components may provide improved structural properties, as they may be larger than a post. Moreover, perimeter components may be active in some versions of the circuit board and inactive in other versions of the circuit board. This may enable a flexible activation of perimeter components that support the shield lid to permit a streamlined assembly process of compact shielded circuit boards without limiting the design process by forcing usage (or non-usage) of specific components.

In a process 406, a shield lid may be attached to the top of the printed circuit board. The shield lid may be coupled to conductive adhesive at the top of posts or integrated component terminations. In certain situations the conductive structure may be welded, soldered, or pre-molded as discussed above. In the method 400 described above, components may be attached to the PCB prior to attachment of the shield frame or shield lid. In some implementations, posts and perimeter components may be first attached to the shield frame. In such situation, the perimeter components and the shield frame lid may form a shield frame that may be coupled to the PCB as a monolithic device. This coupling may be performed employing adhesive conductors, welding, or soldering, which may employ solder balls. In certain situations, the perimeter components may be arranged as an array of components (e.g., array of filters, array of decoupling capacitors) that may provide additional flexibility during the circuit design process without increasing the size of the circuit board, as the new components occupy a region that would have be occupied by a post.

In many situations, the input/output connections of electrical circuit boards may have filters (e.g., LC filters, pi filters, bulkhead filters). In these situations filter components such as capacitors and inductors may be natural choices for a perimeter component of a shield frame. In some situations, semi-conductor components such as diode, transistors, or other discreet semi-conductor components may be used. Note that, due to the currents induced in the integrated ground termination of a component, certain components may be unsuitable for this application, as these induced currents may affect the function of the component within the electrical circuit. Note also that, while the description discusses connections to a ground of the electrical circuit, the devices described herein may be used to couple shield frames to a fixed voltage, such as a positive rail, which may be more appropriate for shielding in some situations.

Shield frames, as the ones described herein, may prevent electromagnetic interferences that may range from 10 Hz to 100 GHz depending on the design of the space between perimeter components and/or posts. For example, shielding from interferences coming from power lines may target a range from 40-100 Hz, while shielding from interferences coming from microwave emissions may go up to 100 GHz. The target interference frequency may be adjusted with changes in the separation between neighboring posts and/or perimeter components, as discussed above. As the distance between elements of the shield frame wall decreases, the frequency of the interfering frequencies blocked by the shield frame may increase. Note that perforations in the shield frame lid should also be adjusted based on the desired frequency be a perforated metal lid instead of a solid metal plate based on the desired frequency noise interference. For example, for 60 GHz frequencies, spacing of around 50 μm may be used.

Advantages provided by embodiments described herein allow for the assembly of shielded, compact circuit boards that employ integrated ground terminations of electrical components in the circuit board. The integrated ground terminations may provide ground electrical connections to the component as well as to the shield frame and the shield wall. This dual performance of the ground terminations may allow an efficient use of space, as the number of dedicated grounding posts may decrease. As a result, the techniques and devices described herein allow for compact shielded circuit boards that may be used in compact devices.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A shielded, printed circuit board comprising:
an electrical component comprising a first termination and a second termination, wherein the second termination is coupled to a ground of the printed circuit board; and
a shield frame lid electrically coupled to the ground of the printed circuit board via the second termination of the electrical component.

2. The shielded, printed circuit board of claim 1, comprising a post that couples the shield frame lid to the ground of the printed circuit board.

3. The shielded, printed circuit board of claim 1, wherein the component comprises a capacitor, an inductor, a resistor, or any combination thereof.

4. The shielded, printed circuit board assembly of claim 1, comprising a filter that comprises the component.

5. The shielded, printed circuit board of claim 4, wherein the filter comprises a bulkhead filter.

6. The shielded, printed circuit board of claim 4, wherein the filter comprises an inductor-capacitor filter.

7. The shielded, printed circuit board of claim 1, wherein the component comprises a third termination and wherein the second termination is disposed between a first component element connected to the first termination of the component and a second component element connected to the third termination of the component.

8. An electrical device comprising:
a circuit substrate;
a plurality of perimeter components attached to the circuit substrate, wherein each perimeter component comprises a ground termination that couples to an electrical ground of the circuit substrate; and
a shield frame lid, wherein the shield frame lid is electrically coupled to the electrical ground of the circuit substrate via the ground terminations of the plurality of perimeter components.

9. The electrical device of claim 8, comprising a plurality of posts that couple the shield frame lid to the electrical ground of the circuit substrate.

10. The electrical device of claim 8, comprising a filter that comprises at least one component of the plurality of perimeter components.

11. The electrical device of claim 8, wherein the ground terminations of the plurality of perimeter components form a shield frame wall of a shield frame that at least partially surrounds at least one of the plurality of perimeter components.

12. The electrical device of claim 8, wherein the maximum separation between perimeter components is less than 1 cm.

13. The electrical device of claim 8, wherein the electrical device comprises a power supply, processing circuitry, a memory, or wireless network circuitry.

14. The electrical device of claim 8, comprising a power supply, processing circuitry, a memory, or wireless network circuitry that is at least partially shielded by a shield frame formed by the shield frame lid and the plurality of perimeter components.

15. The electrical device of claim 8, comprising a memory, a storage, a display, processing circuitry, an input structure, a power source, a network interface or an input/output interface, or any combination thereof, that couples to at least one of the plurality of perimeter components.

16. A method to form a shield frame for a printed circuit board, comprising:
attaching an electrical component to the printed circuit board;
coupling at least one ground terminal of the electrical component to a ground connection of the printed circuit board; and
attaching a shield frame to the ground terminal of the electrical component.

17. The method of claim 16, comprising:
attaching a post to the printed circuit board; and
attaching the shield frame to the post.

18. The method of claim 16, wherein attaching the shield frame to the ground terminal of the electrical component comprises attaching an adhesive conductor to the ground terminal of the electrical component.

19. The method of claim 16, comprising pre-forming a conductor on the ground terminal of the electrical component for subsequent attachment to the shield frame.

20. The method of claim 16, wherein attaching the shield frame to the ground terminal of the electrical component comprises soldering the shield frame to the ground terminal of the electrical component.
